(19) United States
(12) Patent Application Publication
(10) Pub. No.: US 2005/0002265 A1
(43) Pub. Date: Jan. 6, 2005

(54) Header compression

(75) Inventors: Raphael Cassiers, Mechelen (BE); Benoit Christiaens, Mechelen (BE); Timothy Dobson, Cambridge (GB)

Correspondence Address: STERNE, KESSLER, GOLDSTEIN & FOX PLLC, 1100 NEW YORK AVENUE, N.W., WASHINGTON, DC, 20005, US

(73) Assignee: Broadcom Corporation, Irvine, CA (US)

(21) Appl. No.: 10/796,210

(22) Filed: Mar. 10, 2004

Related U.S. Application Data
(60) Provisional application No. 60/483,624, filed on Jul. 1, 2003.

(51) Int. Cl. G11C 8/02

(52) U.S. Cl. 365/232

(57) ABSTRACT

A transmitter unit for transmitting data via a data link is described, wherein the transmitter unit comprises a header compression unit adapted for converting a primary header of a data packet to be transmitted into a corresponding secondary header, with said primary header being related to said secondary header in one-to-one correspondence. The transmitter unit is adapted for transmitting a modified data packet via said data link, said modified data packet comprising the corresponding secondary header. Furthermore, a receiver unit for receiving data transmitted via a data link is described. The receiver unit comprises a header decompression unit adapted for converting a secondary header of a modified data packet received via said data link into a corresponding primary header.

### CROSS-REFERENCE TO RELATED APPLICATIONS

This application claims the benefit of U.S. Provisional Application No. 60/483,624 filed Jul. 1, 2003, the contents of which is hereby incorporated by reference.

### FIELD OF HE INVENTION

This invention relates to a transmitter unit for transmitting data via a data link, and to a receiver unit for receiving data transmitted via a data link. Furthermore, the invention relates to a method for transmitting data, and to a method for receiving data via a data link.

### BACKGROUND OF THE INVENTION

Standardized protocol layers often provide a variety of different features, and for this reason, standard protocols often impose a large overhead on data transmission. In a certain context, a lot of the features and capabilities provided by a certain protocol standard might seem dispensable, and some of the features might not be utilized at all. Together with the user data, large headers have to be transmitted. Accordingly, a significant fraction of the available bandwidth is spent for transmitting header information.

In particular, a lot of overhead is imposed by the protocol standard ATM (Asynchronous Transport Protocol), which is widely used for transmitting all kinds of data traffic over an access network. In ATM, data packets with a packet size of fifty-three bytes are used, with each of said packets comprising an ATM header of five bytes. Only forty-eight bytes of each data packet are available for transmitting user data. Hence, the overhead amounts to about 9.4%. It has to be pointed out that the present invention is not limited to the protocol standard ATM, but can be applied to any protocol standard.

### SUMMARY OF THE INVENTION

The present invention provides a transmitter unit for transmitting data via a data link. The transmitter unit comprises a header compression unit adapted for converting a primary header of a data packet to be transmitted into a corresponding secondary header, with said primary header being related to said secondary header in one-to-one correspondence. The transmitter unit is adapted for transmitting a modified data packet via said data link, said modified data packet comprising the corresponding secondary header.

In one variant, said data packet is an ATM cell, and said primary header is an ATM header.

In another variant, said data link is part of an access network, in particular of an xDSL network.

In yet another variant, said modified data packet is of a fixed packet size.

In another variant, the size of the secondary header is substantially smaller than the size of the primary header.

In yet another variant, the header compression unit is adapted for converting the headers in real-time.

In yet another aspect, the header compression unit is adapted for removing redundancy check bits that are part of the primary header.

In another aspect, said header compression unit is adapted for copying a predefined part of the primary headers' bit sequence to the corresponding secondary header without any modification.

In yet another variant, said header compression unit is adapted for assigning, whenever a previously unknown primary header is encountered for the first time, a secondary header to said primary header.

In yet another variant, said header compression unit comprises at least one lookup table, with said lookup table being accessed for converting a primary header, or a part thereof, into a corresponding secondary header, or a part thereof.

In another variant, the header compression unit is adapted for creating, whenever a secondary header is assigned to a previously unknown primary header, a corresponding entry in the lookup table.

In yet another variant, an entry of said lookup table comprises header information for relating a certain primary header, or a part thereof, to a corresponding secondary header, or a part thereof.

In another aspect, an entry of said lookup table comprises a primary header, or a part thereof, whereby a corresponding secondary header, or a part thereof, is represented by the respective entry number.

In yet another aspect, the header compression unit is adapted for searching the lookup table for an entry that matches with the primary header of a data packet to be transmitted, or with a part thereof, and for fetching, in case of a match, a corresponding secondary header, or a part thereof.

In another variant, said transmitter unit is adapted for transmitting update information packets via said data link, with said update information packets comprising update information for updating at least one lookup table on the part of a receiver unit.

In another variant, each time a new entry in the lookup table is created, an update information packet comprising header information of said entry is transmitted.

In yet another variant, said update information comprises one or more secondary headers, or parts thereof, and for each of said secondary headers, a corresponding primary header said secondary header has been assigned to, or parts thereof.

In yet another aspect, said secondary headers comprise extra bits that are used for transmitting control information.

In another aspect, said secondary headers comprise extra bits for accommodating count values required for transmitting said modified data packets in an inverse multiplexing mode.

The present invention further provides a receiver unit for receiving data transmitted via a data link. The receiver unit comprises a header decompression unit adapted for converting a secondary header of a modified data packet received via said data link into a corresponding primary header, with said secondary header being related to said primary header in one-to-one correspondence.

In one variant, said modified data packet is of a fixed packet size.

In yet another variant, said receiver unit is adapted for performing a cell delineation by counting the bytes received by the receiver unit.

In another aspect, said header decompression unit is adapted for copying a predefined part of the secondary headers' bit sequence to the corresponding primary header without any modification.

In yet another aspect, said header decompression unit comprises at least one lookup table, with said lookup table being accessed for converting a secondary header, or a part thereof, into a corresponding primary header, or a part thereof.

In another variant, an entry of said lookup table comprises header information for relating a certain secondary header, or a part thereof, to a corresponding primary header, or a part thereof.

In yet another variant, said header decompression unit is adapted for using said secondary header, or a part thereof, as an entry number for accessing an entry of the lookup table, with said entry containing a primary header that corresponds to said secondary header, or a part thereof.

In yet another aspect, said receiver unit is adapted for receiving update information packets via said data link, with said update information packets comprising update information for updating said lookup table.

In another variant, the header decompression unit is adapted for regenerating redundancy check bits.

The present invention provides a method for transmitting data via a data link. The method comprising the steps of converting a primary header of a data packet that is to be transmitted via said data link into a corresponding secondary header, with said primary header being related to said secondary header in one-to-one correspondence, and of transmitting a modified data packet via said data link, said modified data packet comprising the corresponding secondary header.

In one variant, the method comprises a step of removing redundancy check bits that are part of the primary header.

In yet another variant, the method comprises a step of copying a predefined part of the primary headers' bit sequence to the corresponding secondary header without any modification.

In another variant, the method comprises a step of accessing a lookup table for converting a primary header, or a part thereof, into a corresponding secondary header, or a part thereof.

In another aspect, a step of transmitting update information packets via said data link, with said update information packets comprising update information for updating at least one lookup table on the part of a receiver unit.

The present invention further provides a method for receiving data transmitted via a data link, said method comprising the steps of converting a secondary header of a modified data packet that has been received via said data link into a corresponding primary header, with said secondary header being related to said primary header in one-to-one correspondence.

Furthermore, the present invention provides a method of data transport over an access network, comprising the steps of receiving a data packet having a header; of reducing the header in the data packet to create a modified data packet; and of transmitting the modified data packet over the access network.

The invention can be partly or entirely embodied or supported by one or more suitable software programs, which can be stored on or otherwise provided by any kind of data carrier, and which might be executed in or by any suitable data processing unit. Software programs or routines are preferably applied for executing the steps of the methods described above.

According to another aspect of the invention, a receiver unit for receiving data transmitted via a data link comprises:
a header decompression unit adapted for converting a secondary header of a modified data packet received via said data link into a corresponding primary header, with said secondary header being related to said primary header in one-to-one correspondence.

Advantageously, said modified data packets are of fixed packet size.

Advantageously, said receiver unit is adapted for performing a cell delineation by counting the bytes received by the receiver unit.

Advantageously, said header decompression unit is adapted for copying a predefined part of the secondary headers' bit sequence to the corresponding primary header without any modification.

Advantageously, said header decompression unit comprises at least one lookup table, with said lookup table being accessed for converting a secondary header, or a part thereof, into a corresponding primary header, or a part thereof.

Advantageously, an entry of said lookup table comprises header information for relating a certain secondary header, or a part thereof, to a corresponding primary header, or a part thereof.

Advantageously, said header decompression unit is adapted for using said secondary header, or a part thereof, as an entry number for accessing an entry of the lookup table, with said entry containing a primary header that corresponds to said secondary header, or a part thereof.

Advantageously, said receiver unit is adapted for receiving update information packets via said data link, with said update information packets comprising update information for updating said lookup table.

Advantageously, the header decompression unit is adapted for regenerating redundancy check bits.

According to another aspect of the invention, a method for transmitting data via a data link comprises the steps of:
converting a primary header of a data packet that is to be transmitted via said data link into a corresponding secondary header, with said primary header being related to said secondary header in one-to-one correspondence; and
transmitting a modified data packet via said data link, said modified data packet comprising the corresponding secondary header.

Advantageously, the method comprises a step of removing redundancy check bits that are part of the primary header.

Advantageously, the method comprises a step of copying a predefined part of the primary headers' bit sequence to the corresponding secondary header without any modification.

Advantageously, the method comprises a step of accessing a lookup table for converting a primary header, or a part thereof, into a corresponding secondary header, or a part thereof.

Advantageously, the method comprises a step of transmitting update information packets via said data link, with said update information packets comprising update information for updating at least one lookup table on the part of a receiver unit.

According to another aspect of the invention, a method for receiving data transmitted via a data link comprises the step of:
converting a secondary header of a modified data packet that has been received via said data link into a corresponding primary header, with said secondary header being related to said primary header in one-to-one correspondence.

According to another aspect of the invention, a method of data transport over an access network comprises the steps of
receiving a data packet having a header;
reducing the header in the data packet to create a modified data packet; and
transmitting the modified data packet over the access network.

It is appreciated that these and other aspects of the invention will become apparent to those skilled in the art in the detailed description and drawings contained herein.

### BRIEF DESCRIPTION OF THE DRAWINGS

FIG. 1 gives an overview of the upstream and downstream transmission of data packets via an access network;

FIG. 2 depicts the first four bytes of an uncompressed ATM header, together with a corresponding compressed header;

FIG. 3 shows a header lookup table comprising 16 entries; and

FIG. 4 is an example computer system useful for implementing the present invention.

### DETAILED DESCRIPTION OF THE INVENTION

The present invention provides a transmitter unit for transmitting data via a data link. The transmitter unit comprises a header compression unit adapted for converting a primary header of a data packet to be transmitted into a corresponding secondary header, with said primary header being related to said secondary header in one-to-one correspondence. The transmitter unit is adapted for transmitting a modified data packet via said data link, said modified data packet comprising the corresponding secondary header.

In a given context, it might be favourable to employ a certain well-known standard protocol for transmitting data via a data link. Compared to the respective demands, the overhead imposed by the respective protocol standard might be over dimensioned, though, because the protocol standard might provide a lot of additional features that are not really useful in the respective context. In fact, a lot of the features provided by the respective protocol standard might not even be utilized.

For example, the header format of the respective standard protocol might comprise data fields that correspond to features that are not even used. Therefore, when transmitting data packets via the data link, every single header might comprise one or more constant bit sequences. With respect to the features that are actually required in a certain environment, the primary headers seem to be oversized, and the transmission of said headers uses up too much of the bandwidth provided by the data link.

According to embodiments of the present invention, each of the primary headers is related in one-to-one correspondence to a corresponding secondary header, whereby the secondary header might e.g. be of much smaller size than the primary header. The secondary header might e.g. be realized as a short tag that allows to identify the corresponding primary header. The respective secondary header allows to unambiguously identify the underlying primary header.

By replacing the primary headers with corresponding secondary headers, the transmission overhead can be considerably reduced. Especially if the primary headers comprise features that are dispensable in a certain context, the size of the headers can be reduced significantly. The overhead is decreased, and for this reason, data can be transmitted at a higher data rate. As a result, the available bandwidth of the data link is used more efficiently.

In one variant, said data packets are ATM cells, and said primary headers are ATM headers. The protocol standard ATM (Asynchronous Transport Mode) provides a large set of capabilities like e.g. redundancy checks, wide addressing capabilities for millions of virtual paths and virtual channels, flexible multiplexing of data packets with different quality-of-service (QoS) requirements, link management, BER (Bit Error Rate) monitoring, etc. In a certain application, one or more of said features might be unnecessary. For example, the redundancy check bits might be redundant, because higher protocol layers might provide a redundancy check as well. Furthermore, a respective data link might be implemented as a point-to-point connection, and in this context, the wide addressing capabilities of ATM might be over dimensioned, and the addressing capabilities provided by ATM might only be used to a very small extent. When monitoring hundreds of data packets, only a few different headers might be encountered. In these cases, it is advantageous to replace the full-size ATM headers by corresponding secondary headers of much smaller size. In particular, the 5 byte ATM headers might e.g. be replaced by secondary headers of e.g. 1 byte.

Said data link might be part of an access network, in particular of an xDSL network. In a core network, a high overhead is not an issue, because there is enough transmission bandwidth available. In the access network, however, a high overhead represents a serious drawback due to the limited data transport bandwidth available. According to xDSL protocol standards, the data link between a central office equipment (CO) and a customer premise equipment (CPE) is basically realized as a point-to-point connection. In the access network, the wide addressing capabilities provided by protocol standards such as e.g. ATM are therefore not used. In order to decrease the overhead in the access network, the primary headers can be replaced by secondary headers of reduced size.

Preferably, the modified data packets are of fixed packet size. If the modified data packets are of constant size, it will be simple to detect where a first data packet ends and where the subsequent data packet starts.

Preferably, the size of the secondary headers is substantially smaller than the size of the primary headers. For example, a 5 byte ATM header can be replaced by a secondary header of 1 byte. While an ATM packet with a full-size ATM header comprises fifty-three bytes, a modified ATM packet with a compressed header only comprises forty-nine bytes. Hence, the packets' overhead can be reduced from 9.4% to about 2.1%.

The header compression unit might e.g. convert the headers in real-time. All the necessary operations for replacing the primary headers by their corresponding secondary headers can be carried out at real-time. Thus, it is not necessary to provide large buffers on the part of the transmitter.

The header compression unit is adapted for removing redundancy check bits that are part of the primary header. On the part of the receiver, said redundancy check bits can be regenerated, and therefore, they do not necessarily have to be transmitted. Often, higher protocol layers comprise redundancy check bits as well. In this case, transmission errors can be detected even if the primary headers' redundancy check bits are removed. Alternatively, the well-known payload of idle packets may be used for monitoring the bit error rate (BER).

Furthermore, said header compression unit might be adapted for copying a predefined part of the primary headers' bit sequence to the corresponding secondary header without any modification. For example, the primary headers' most characteristic bits might be copied to the secondary header without modification. For example, the primary headers' payload type identifier (PTI) bits might be copied to the corresponding secondary headers without any changes. Then, in a subsequent step, the remaining bits of a primary header can be converted into a corresponding part of a secondary header. After the most characteristic bits have been taken care of, the remaining bits might only comprise a small number of different bit patterns. Hence, by considering the most characteristic bits in advance, header conversion can be simplified. For example, in case a header lookup table is utilized for converting the headers, the number of lookup table entries required for header translation is significantly reduced.

The header compression unit might be adapted for assigning, whenever a previously unknown primary header is encountered for the first time, a secondary header to said primary header. After a secondary header has been assigned to a certain primary header, the one-to-one correspondence between these headers is stored, and further on, the primary header will be replaced by the corresponding secondary header. Hence, the relations between the primary headers and the corresponding secondary headers are built up automatically during operation of the header compression unit. Because of this self-learning capability, no initial configuration of the header compression unit is required.

The header compression unit might comprise at least one lookup table, with said lookup table being accessed for converting a primary header, or a part thereof, into a corresponding secondary header, or a part thereof. A lookup table is well-suited for converting the packets' primary headers, or parts thereof, into corresponding secondary headers, or parts thereof. The lookup table is accessed in accordance with a primary header, or a part thereof, and from the lookup table, a corresponding secondary header, or a part thereof, is obtained.

In another variant, the header compression unit is adapted for creating, whenever a secondary header is assigned to a previously unknown primary header, a corresponding entry in the lookup table. Initially, the lookup table might e.g. be filled with headers related to idle cells. During further operation, the lookup table is subsequently filled with entries that define one-to-one correlations between primary headers and corresponding secondary headers. Due to this self-learning capability, the lookup table builds up automatically during operation of the header compression unit.

An entry of said lookup table might comprise header information for relating a certain primary header, or a part thereof, to a corresponding secondary header, or a part thereof. Each entry of the lookup table represents a one-to-one correlation between a certain primary header and a corresponding secondary header that has been assigned to the primary header. During further operation of the header compression unit, the one-to-one correlation as defined by the entry in the lookup table is used for converting primary headers, or parts thereof, into corresponding secondary headers, or parts thereof.

In another embodiment, an entry of said lookup table might comprise a primary header, or a part thereof, whereby a corresponding secondary header, or a part thereof, is represented by the respective entry number. The entry number of the lookup table is used as a secondary header that represents the corresponding primary header, with the primary header, or a part thereof, being stored in the respective entry. In this embodiment, the entries of the lookup table do not necessarily have to comprise the secondary headers, or parts thereof, because the secondary headers are indicated by the entry number. Hence, the set-up of the lookup table is simplified. On the part of a receiver unit, a secondary header of a modified data packet might e.g. be converted back into the corresponding primary header. If the secondary header is equal to the entry number, the respective entry of the receiver's lookup table can be accessed immediately, and the corresponding primary header contained therein can be read out.

In yet another aspect, the header compression unit is adapted for searching the lookup table for an entry that matches with the primary header of a data packet to be transmitted, or with a part thereof, and for fetching, in case of a match, a corresponding secondary header, or a part thereof. On the part of the transmission unit, the lookup table is searched for an entry containing the primary header of the data packet to be sent. Once the respective entry is found, the corresponding secondary header can be obtained there from. For example, the respective entry number might be determined, with said entry number representing said secondary header, or a part thereof. In an alternative embodiment, the secondary header, or a part thereof, might be stored as a part of the respective entry and can be obtained by performing a read access.

In another variant, said transmitter unit is adapted for transmitting update information packets via said data link, with said update information packets comprising update information for updating at least one lookup table on the part of a receiver unit. At the receiver unit, a secondary header of a modified data packet has to be converted back to the corresponding primary header. For this purpose, the entries of the receiver's lookup table have to be equal to the entries of the transmitter's lookup table. This can be accomplished by transmitting update information from the transmitter to the receiver.

In one variant, each time a new entry in the lookup table is created, an update information packet comprising header information of said entry is transmitted. Hence, the at least one lookup table on the part of the receiver unit can be updated as soon as possible. In particular, the at least one lookup table on the part of the receiver unit can be updated before a modified data packet with a header that corresponds to the new entry is received.

The update information might comprise one or more secondary headers, or parts thereof, and for each of said secondary headers, a corresponding primary header said secondary header has been assigned to, or parts thereof. Hence, the one-to-one correspondences that have been established between primary headers and corresponding secondary headers are communicated by sending update information packets to the receiver unit.

The secondary headers may further comprise extra bits that are used for transmitting control information. In particular, said secondary headers might comprise extra bits for accommodating count values required for transmitting the modified data packets in an inverse multiplexing mode. In an inverse multiplexing mode, the data packets are transmitted via two or more different channels in parallel. If the respective transmission rates of the channels are not equal to each other, the order of the data packets might get lost during the transmission. At the receiver unit, the order of the data packets has to be re-established. For this purpose, count values are assigned to the data packets, with said count values indicating the packets' initial order. These count values can be transmitted as a part of the secondary headers.

The present invention further provides a receiver unit for receiving data transmitted via a data link. The receiver unit comprises a header decompression unit adapted for converting a secondary header of a modified data packet received via said data link into a corresponding primary header, with said secondary headers being related to said primary headers in one-to-one correspondence. Whenever a modified data packet comprising a secondary header has been received by the receiver unit, the secondary header is converted back into the underlying primary header. Thus, the original data packet is regenerated on the part of the receiver. There is no difference between the original data packets and the data packets as regenerated by the receiver unit. From the point of view of an external environment, the header compression decompression is transparent, which means that a user does not even notice that the headers have been transmitted in a compressed mode.

In one variant, said modified data packets are of fixed packet size. The modified data packets comprise a compressed header and the payload of the original data packet. For example, in ATM, the compressed header comprises 1 byte, and the payload comprises forty-eight bytes. Hence, each of the modified ATM packets comprises forty-nine bytes of data. If the modified data packet is of constant size, it will be simple to detect where a first data packet ends and where the subsequent data packet starts.

The receiver unit is adapted for performing a cell delineation by counting the bytes received by the receiver unit. If packet transmission is aligned to start of show time, or if the respective offset of data transmission relative to start of show time is known, the data packets can be distinguished by counting the bytes as they arrive at the receiver unit.

The header decompression unit might be adapted for copying a predefined part of the secondary headers' bit sequence to the corresponding primary header without any modification. The bits that have been copied from the primary header to the secondary header on the part of the header compression unit are now copied back to the primary header again.

The header decompression unit might comprise at least one lookup table, with said lookup table being accessed for converting a secondary header, or a part thereof, into a corresponding primary header, or a part thereof. For example, for translating secondary headers, or parts thereof, the kind of lookup table that is used on the part of the transmitter might be used on the part of the receiver as well. An entry of said lookup table might comprise header information for relating a certain secondary header, or a part thereof, to a corresponding primary header, or a part thereof.

The header decompression unit might be adapted for using said secondary header, or a part thereof, as an entry number for accessing an entry of the lookup table, with said entry containing a primary header that corresponds to said secondary header, or a part thereof. In this embodiment, the secondary header, or a part thereof, can be used for addressing the respective entry containing the desired primary header, or a part thereof.

The receiver unit might receive update information packets via said data link, with said update information packets comprising update information for updating said lookup table. Whenever a new entry of the transmitter's lookup table is created, the receiver's lookup table is updated accordingly.

The header decompression unit might be adapted for regenerating redundancy check bits. Thus, the original headers can be regenerated, even if the redundancy check bits have not been transmitted.

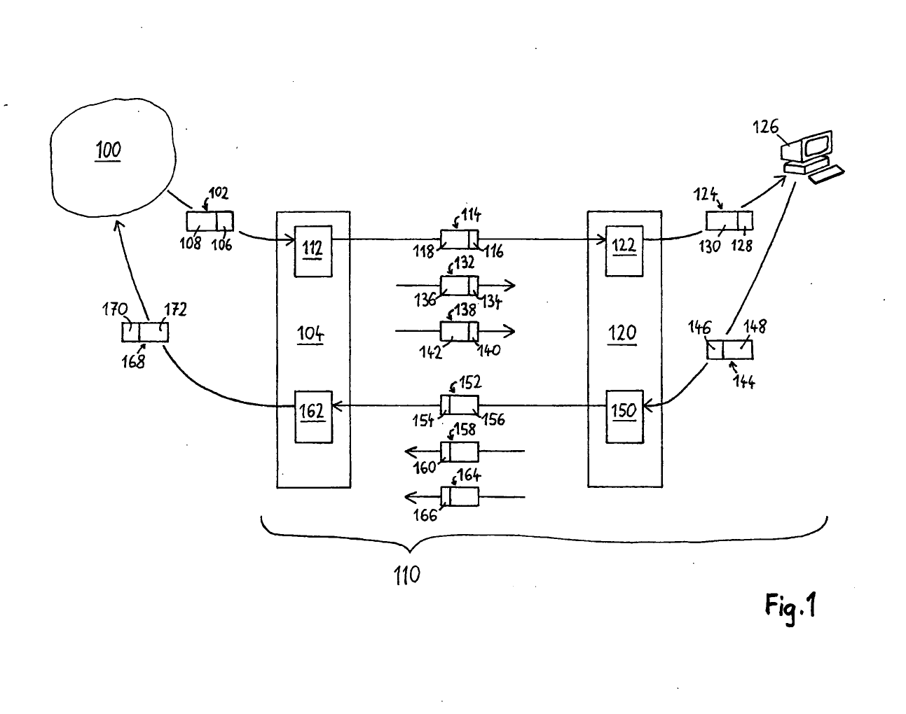

FIG. 1 gives an overview of data transport in an access network, e.g. in a xDSL access network, according to an embodiment of the present invention. Via a core network 100, various different providers might transmit ATM (Asynchronous Transport Mode) packets 102 to a Central Office Equipment (CO) 104. The ATM packets 102 are adapted for transporting data related to services such as e.g. internet, voice over IP, video, etc. Each of the ATM packets 102 comprises an ATM header 106 of 5 bytes, followed by forty-eight bytes of payload 108. The protocol standard ATM, which is commonly used as a layer 2 transport protocol, provides features such as multiple virtual channels, link monitoring, traffic prioritization, flexible multiplexing of data packets with different quality-of-service requirements, on-line BER (Bit Error Rate) monitoring, rate adaptation, etc. The ATM header comprises addressing capabilities for a multitude of virtual paths (VP) and virtual channels (VC), priority bits, Payload Type Identifier (PTI) bits, etc. Furthermore, the ATM header comprises a HEC (Header Error Check) byte that allows to check whether the header has been transmitted correctly. Because of these features, the ATM packet overhead is very large: in an ATM cell of fifty-three bytes, five bytes of said fifty-three bytes are used up by the ATM header, which corresponds to an overhead of 9.4%. For data traffic related to different providers and different services, only a few virtual paths and virtual channels are actually used. In the context of ATM transport over the access network 110, the wide ATM addressing capability is dispensable. Furthermore, for most IP traffic over ATM, the protocol standard AAL5 (ATM Adaptation Layer 5) is used as an encapsulation layer. AAL5 comprises a Cyclic Redundancy Check (CRC). For this reason, also the header check (HEC, Header Error Check) provided by ATM is to some extent redundant.

In order to reduce the headers' redundancies, the central office equipment 104 comprises a header compression unit 112 that replaces each ATM header by a corresponding compressed header, with said replacement being performed at real time. For example, in order to reduce the overhead, the redundancy check byte (HEC byte) of an ATM header might be omitted. Furthermore, the remaining four bytes of the ATM header can be replaced by a compressed header of reduced size. The modified ATM packets 114, which comprise a compressed ATM header 116 and forty-eight bytes of payload 118, are transmitted from the Central Office Equipment (CO) 104 to the Customer Premise Equipment (CPE) 120.

While the ATM packets 102 comprise fifty-three bytes of data each, the modified ATM packets 114 only comprise forty-nine bytes of data. Thus, header compression allows to reduce ATM packet overhead in the downstream direction from 9.4% to about 2.1%.

On the part of the Customer Premise Equipment 120, the compressed headers of the modified ATM packets have to be converted back into the original headers. For this purpose, the Customer Premise Equipment 120 comprises a header decompression unit 122 that is adapted for replacing the compressed headers by the corresponding original ATM headers, whereby the original headers' redundancy check bytes are regenerated. The data packets 124 received by the user 126 comprise an original ATM header 128 and forty-eight bytes of payload 130. Hence, the data packets 124 received by the user 126 comply with the regular ATM protocol standard; the user 126 does not even notice that a header compression has been performed.

In addition to the data packets 114, idle packets 132 are transmitted from the CO 104 to the CPE 120. The access network 110 provides a certain bandwidth for data transmission between the CO 104 and the CPE 120. In order to maintain the data link between the CO 104 and the CPE 120, a continuous data stream of well-defined bandwidth has to be transmitted via the data link. At the CO 104, the ATM packets 102 represent a data stream of variable bandwidth. In order to adapt the data rate of the ATM traffic to the fixed bandwidth provided by the access network 110, the remaining bandwidth is filled up by transmitting idle packets 132. Said idle packets 132, which are generated by the CO 104 itself, comprise a compressed header 134 and forty-eight bytes of predefined data 136.

The CO 104 also generates update information packets 138. By means of these update information packets 138, update information related to header compression is transmitted from the CO's header compression unit 112 to the CPE's header decompression unit 122. Each of the update information packets 138 comprises a compressed header 140 and forty-eight bytes of update information 142.

So far, data transmission in the downstream direction from the CO 104 to the CPE 120 has been discussed. The implementation shown in FIG. 1 is fully symmetric with respect to downstream and upstream data transmission. For transmitting data to the core network 100 in the upstream direction, the user 126 provides ATM packets 144 to the CPE 120, with each of the ATM packets 144 comprising an ATM header 146 and forty-eight bytes of payload 148. In the CPE's header compression unit 150, each ATM header is converted into a corresponding compressed header. The modified ATM packets 152, which comprise a compressed header 154 and forty-eight bytes of payload 156, are transmitted from the CPE 120 to the CO 104. While the ATM packets 144 comprise fifty-three bytes of data each, the modified ATM packets 152 only comprise forty-nine bytes of data. Hence, ATM packet overhead can be reduced from 9.4% to about 2.1%. Also in the upstream direction, the data rate of ATM traffic might be smaller than the fixed bandwidth provided by the xDSL link. For this reason, idle packets 158 might be inserted, whereby the idle packets 158 are generated by the CPE 120. Each of the idle packets 158 comprises a compressed header 160.

On the part of the CO 104, the header decompression unit 162 is adapted for converting the compressed headers of received data packet into the corresponding ATM headers. Furthermore, the respective HEC byte is regenerated by the CO 104. In order to update the header decompression unit 162 of the CO 104 in accordance with the header compression unit 150, update information packets 164 generated by the CPE 120 are transmitted to the CO's header decompression unit 162. Each of the update information packets 164 comprises a compressed header 166. The CO 104 provides ATM packets 168 to the core network 100, with each of said ATM packets 168 comprising a full-size ATM header 170 and forty-eight bytes of payload 172.

It has to be pointed out that the present invention is not limited to ATM traffic being transmitted over an xDSL access network. The header compression and decompression proposed by the present invention might as well be used for reducing the overhead of data traffic according to any other protocol standard.

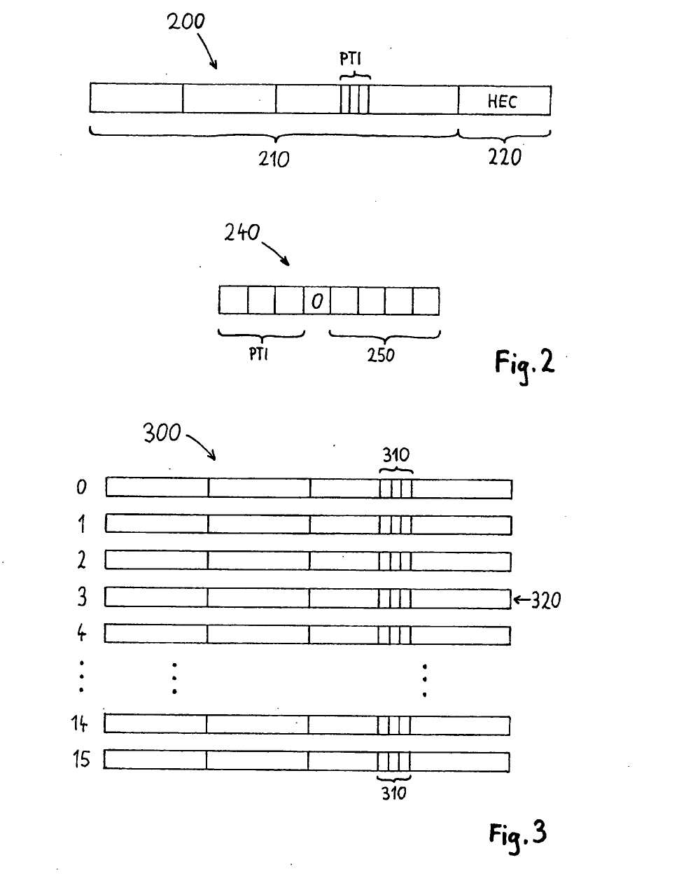

In FIG. 2, an ATM header 200 is shown in more detail. The ATM header 200 comprises four bytes 210 of header information and one HEC (Header Error Check) byte 220, whereby the HEC byte 220 might e.g. be derived from the four bytes 210 by performing XOR operations. The header information comprises VP/VC (virtual path/virtual channel) routing information, priority bits, link monitoring data, etc. Furthermore, the four bytes 210 of header information comprise Payload Type Identifier (PTI) bits [2 . . . 0] that indicate the respective payload type of the subsequent data. For example, the PTI bits allow to distinguish between maintenance traffic that has to be routed to a management entity and regular data traffic that is routed to a respective application. In general, an idle packet is identified by means of a reserved 4-byte header.

For converting the ATM header 200 into a corresponding compressed header 240, the HEC byte 220 is omitted on the part of the header compression unit. The remaining four bytes 210 are converted by means of a header lookup table. In FIG. 3, a header lookup table 300 for performing header conversion is shown, with the header lookup table 300 comprising up to sixteen entries. Each entry comprises a complete ATM header (without HEC byte), whereby the PTI bits are replaced by zeros. Whenever a header compression unit receives an ATM packet comprising an ATM header, the header lookup table 300 is searched for the first four bytes of the data packet's ATM header. During this search, the PTI bits of the received ATM header are set to zero, and therefore, the values of the PTI bits are excluded when comparing the received ATM header with the entries of the header lookup table.

If the header lookup table 300 contains an entry that matches the received packet's ATM header, the ATM header will further on be identified by the respective entry number. For example, if the four bytes stored in entry 320 match with the first four bytes of the received ATM header, the received ATM header will be identified by the corresponding entry number “3”. Said entry number is copied to the data field 250 of the compressed header 240, which comprises bits [3 . . . 0] of the compressed header 240. Bit [4] of the compressed header 240 is set to zero; bit [4] might e.g. be used later on for addressing thirty-two (instead of sixteen) lookup table entries. The PTI bits [2 . . . 0] of the ATM header 200, which have not been used for accessing the header lookup table 300, are copied without modification to the bits [7 . . . 5] of the compressed header 240. Hence, the compressed header 240 comprises one byte of header information, with bits [7 . . . 5] containing Payload Type Identification (PTI) bits, and with bits [3 . . . 0] containing an entry number of the header lookup table 300.

The compressed header might further comprise additional data fields for transmitting additional information. For example, in certain contexts, it might be advantageous to use the accumulated bandwidths of two or more channels for transmitting a stream of ATM data traffic. Solutions of this kind have previously been referred to as “ATM inverse multiplexing”. In this case, it is necessary to keep track of the respective order of the data packets, because this order might get lost during transmission. For example, the transmission rate of a first channel might be significantly higher than the transmission rate of a second channel. Therefore, counter values indicating the respective order of data packets, or of groups of data packets, might be added to the compressed headers. By means of these counter values, the data stream can be reassembled on the part of the receiver.

Whenever a new kind of data traffic is detected, the header compression unit will create a new lookup table entry containing the previously unknown ATM header, whereby the header's PTI bits are replaced by zeros. During the course of data transmission, the lookup table builds up automatically. Initially, the entries in the header lookup table 300 might be filled with the idle cell's ATM header.

In an environment as shown in FIG. 1, data packets related to different services like e.g. internet, Voice over IP (VoIP), video, etc. might comprise different ATM headers. Furthermore, data traffic related to different providers might comprise different ATM headers. Due to the point-to-point characteristics of the data transmission between the CO 104 and the CPE 120, however, the number of virtual paths and virtual channels required for transmitting the various kinds of data traffic is generally rather small. The wide addressing capabilities of ATM are only utilized to a very small extent. For this reason, a header lookup table 300 comprising up to sixteen different entries is well-suited for performing the above described header compression. If data traffic comprising more than sixteen different ATM headers is transmitted via the data link, it will be necessary to implement some kind of Least Recently Used (LRU) strategy for replacing the entries of the header lookup table 300.

After the modified data packets have been transmitted to the respective receiver unit, the compressed headers of said modified data packets are decompressed by the receiver's respective header decompression unit (e.g. by the header decompression units 122, 162 shown in FIG. 1). The respective header decompression unit is adapted for converting the compressed header 240 of a modified data packet into the corresponding ATM header 200. For this purpose, the header decompression unit also comprises a header lookup table as shown in FIG. 3, whereby the entries of the receiver's lookup table have to be identical with the entries of the transmitter's lookup table. This can be accomplished by transmitting header update information from the transmitter to the receiver whenever a new entry is added to the transmitter's header lookup table. The header update information has to comprise both the entry numbers and the corresponding uncompressed ATM headers.

In order to access one of the entries of the receiver's header lookup table, the entry number of the compressed header 240 is used for addressing the header lookup table. For example, if the lookup entry number is equal to “3”, the entry 320 will be accessed. The entry 320 contains the first four bytes of the corresponding full size ATM header, whereby the PTI bits 310 have been set to zero. In order to fully recover the four bytes 210 of the ATM header 200, the PTI bits of the compressed header 240 are copied to the respective bit positions of the ATM header. Next, the HEC byte 220, which has not been transmitted via the access network, is derived from the four bytes 210 of the ATM header 200. After the HEC byte 220 has been regenerated, both the full size ATM header 200 and the corresponding forty-eight bytes of payload are available, and hence, the original ATM packet can be reassembled on the part of the receiver unit.

In the present embodiment of the invention, so-called Header Translation Cells (HTCs) are used for transmitting header update information from the transmitter to the receiver. The header translation cells correspond to the update information packets 138, 164 shown in FIG. 1. A header translation cell comprises a compressed header of one byte and forty-eight bytes of header information. Both the idle cells and the HTCs are generated by the receiver unit itself. Both the idle cells and the HTCs are not related to the transmission of ATM traffic, and for this reason, the idle cell's header and the HTC's header do not have to be translated into a corresponding full-size ATM header. The compressed headers of the idle cells and the HTCs comprise an entry number indicating a corresponding entry of the header lookup table, and preferably, one common entry number, e.g. the entry number “0”, is used both in the idle cells' and in the HTCs' headers. However, idle cells and HTCs can be distinguished from each other by means of their respective PTI bits. In case the header's PTI bit [2] is equal to 0, the respective data packet is an idle cell, and in case PTI bit [2] is equal to 1, the data packet is an HTC (Header Translation Cell).

The following format shows how header information can be transmitted as a part of the HTC's payload:
byte 0 bits [4 . . . 0] contain the value of a wrap-around modulo 32 counter, whereby the values of said counter allow to identify corresponding requests and responses. Currently, this data field is not used at RX side.
byte 0 bits [5 . . . 0] contain a command ID. Only command ID 0×0 is defined; other values are reserved for future use.
byte 1 contains lookup entry number #1;
bytes [5 . . . 2] contain the corresponding ATM header #1;
byte 6 contains lookup entry number #2;
bytes [10 . . . 7] contain the corresponding ATM header #2;
byte 36 contains lookup entry number #8;
bytes [40 . . . 37] contain the corresponding ATM header #8;
bytes [43 . . . 41] are reserved for future use;
bytes [47 . . . 44] contain CRC32 check bytes.

Hence, a header translation cell allows to transmit up to eight full size ATM headers, together with the corresponding lookup entry numbers, from the transmitter to the receiver.

Whenever a new entry is created in the transmitter's header lookup table, a HTC comprising the respective entry number and the corresponding full size ATM header has to be transmitted to the receiver. After the respective HTC has been issued, the respective entry may be used for header translation on the part of the transmitter.

In order to make the header translation work, it is important that the header information stored in the receiver's header lookup table is correct. For this reason, each HTC comprises CRC32 redundancy check bytes. CRC32 is the same CRC standard as used in an AAL5 frame. On the part of the receiver, the CRC32 bytes allow to determine, for each HTC that has been received, if the HTC is correct or not. The reliability can be further improved by transmitting the HTCs in an acknowledged mode. Whenever a HTC is received correctly, the receiver transmits an acknowledgement back to the transmitter. If the transmitter does not receive an acknowledgement for a HTC within a predefined period of time, it will retransmit the respective HTC. Instead of issuing acknowledgements for each HTC, the HTCs may be transmitted at a constant rate from the transmitter to the receiver, e.g. at a rate of one HTC per second. In this embodiment, the HTCs are transmitted at regular time intervals, no matter whether the entries of the transmitter's header lookup table have been changed or not. If a certain HTC is not transmitted correctly, the subsequent HTCs will contain the missing header information.

The header compression as described above allows to preserve most of ATM's features and capabilities. For instance, though the compressed headers might not comprise HEC bytes, packet delineation can be performed in a simple and straightforward manner. The modified data packets 114, 152 that are exchanged between the CO 104 and the CPE 120 have a fixed packet size of forty-nine bytes. If there is an alignment of the data packets relative to the start of showtime, or if the relative offset between the first byte of the first data packet and the start of showtime is known, packet delineation can be performed by counting the bytes received by the receiver unit. Even in case of high BER, or in case of micro-interruptions, cell alignment is not lost.

Furthermore, though the compressed headers might not comprise HEC bytes, it is still possible to monitor the bit error rate (BER). Generally, the payload of idle packets comprises a well-known predefined bit pattern. If an idle packet is received, the receiver might compare the received bit pattern with said well-known bit pattern. As a result of this comparison, the number of bit errors per idle packet can be determined, and the actual bit error rate (BER) can be derived there from.

A flexible multiplexing of data packets with different quality-of-service requirements can be performed as before, because the header compression provided by the present invention does not affect the scheduling on the part of the transmitter unit.

The header compression is fully transparent, and hence, a highly standardised interface is provided to the respective environment.

Furthermore, features like e.g. link management capabilities, rate adaptation, the possibility to perform ATM inverse multiplexing, etc. are not hampered by the header compression according to embodiments of the present invention.

FIGS. 1-3 are conceptual illustrations allowing an explanation of the present invention. It should be understood that embodiments of the present invention could be implemented in hardware, firmware, software, or a combination thereof. In such an embodiment, the various components and steps would be implemented in hardware, firmware, and/or software to perform the functions of the present invention. That is, the same piece of hardware, firmware, or module of software could perform one or more of the illustrated blocks (i.e., components or steps).

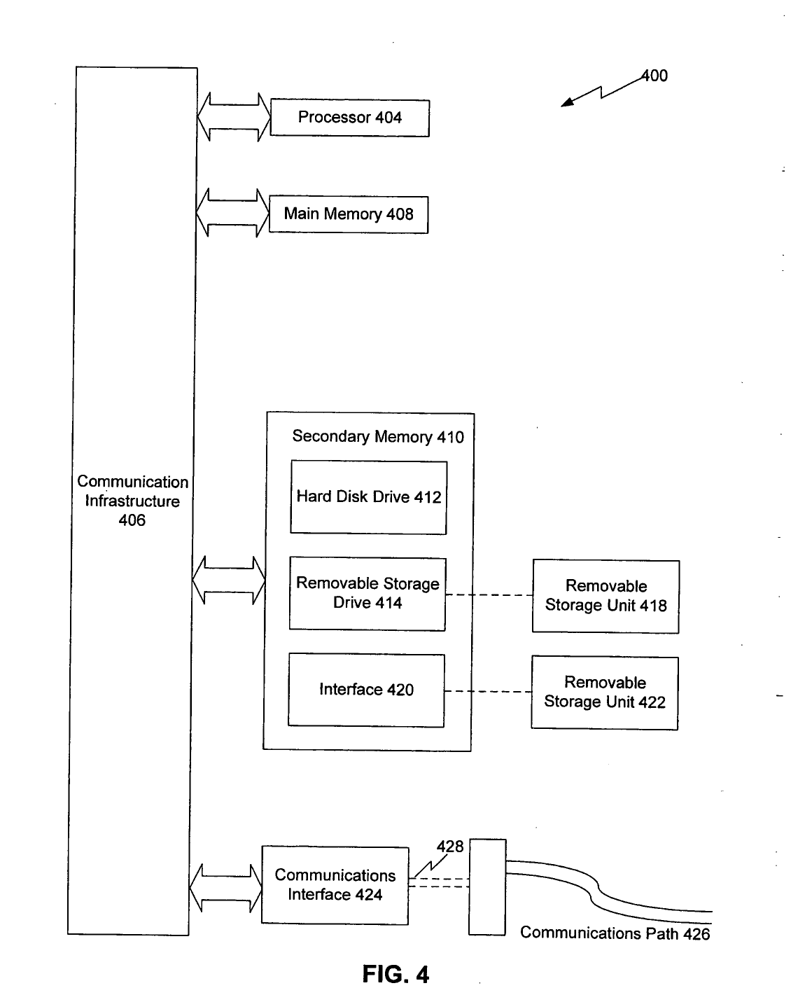

Additionally, the present invention can be implemented in one or more computer systems or other processing systems, capable of carrying out the functionality described herein. Referring to FIG. 4, an example computer system 400 useful in implementing the present invention is shown. Various embodiments are described in terms of this exemplary computer system 400. After reading this description, it will become apparent to a person skilled in the relevant art(s) how to implement the invention using other computer systems and/or computer architectures.

The computer system 400 includes one or more processors, such as processor 404. Processor 404 can be a special purpose or a general purpose digital signal processor. The processor 404 is connected to a communication infrastructure 406 (e.g., a communications bus, cross-over bar, or network).

Computer system 400 also includes a main memory 408, preferably random access memory (RAM), and can also include a secondary memory 410. The secondary memory 410 can include, for example, a hard disk drive 412 and/or a removable storage drive 414, representing a floppy disk drive, a magnetic tape drive, an optical disk drive, etc. The removable storage drive 414 reads from and/or writes to a removable storage unit 418 in a well-known manner. Removable storage unit 418, represents a floppy disk, magnetic tape, optical disk, etc. which is read by and written to removable storage drive 414. As will be appreciated, the removable storage unit 418 includes a computer usable storage medium having stored therein computer software (e.g., programs or other instructions) and/or data.

In alternative embodiments, secondary memory 410 includes other similar means for allowing software and/or data to be loaded into computer system 400. Such means include, for example, a removable storage unit 422 and an interface 420. Examples of such means include a program cartridge and cartridge interface (such as that found in video game devices), a removable memory chip (such as, an EPROM or PROM) and associated socket, and other removable storage units 422 and interfaces 420 which allow software and data to be transferred from the removable storage unit 422 to computer system 400.

Computer system 400 can also include a communications interface 424. Communications interface 424 allows software and/or data to be transferred between computer system 400 and external devices. Examples of communications interface 424 include a modem, a network interface (such as an Ethernet card), a communications port, a PCMCIA slot and card, etc. Software and data transferred via communications interface 424 are in the form of signals 428 which can be electronic, electromagnetic, optical or other signals capable of being received by communications interface 424. These signals 428 are provided to communications interface 424 via a communications path (i.e., channel) 426. Communications path 426 carries signals 428 and can be implemented using wire or cable, fiber optics, a phone line, a cellular phone link, an RF link, free-space optics, and other communications channels.

In this document, the terms “computer program medium” and “computer usable medium” are used to generally refer to media such as removable storage unit 418, removable storage unit 422, a hard disk installed in hard disk drive 412, and signals 428. These computer program products are means for providing software to computer system 400. The invention, in an embodiment, is directed to such computer program products.

Computer programs (also called computer control logic or computer readable program code) are stored in main memory 408 and/or secondary memory 410. Computer programs can also be received via communications interface 424. Such computer programs, when executed, enable the computer system 400 to implement the present invention as discussed herein. In particular, the computer programs, when executed, enable the processor 404 to implement the processes of the present invention, such as the method(s) implemented using, for example, header compression unit 112, header decompression unit 122, header compression unit 150, header decompression unit 162, and/or other system components of the system described above with reference to FIGS. 1-3. Accordingly, such computer programs represent controllers of the computer system 400.

In an embodiment where the invention is implemented using software, the software can be stored in a computer program product and loaded into computer system 400 using removable storage drive 414, hard drive 412 or communications interface 424. The control logic (software), when executed by the processor 404, causes the processor 404 to perform the functions of the invention as described herein.

In another embodiment, the invention is implemented primarily in hardware using, for example, hardware components such as application specific integrated circuits (ASICs). Implementation of the hardware state machine so as to perform the functions described herein will be apparent to persons skilled in the relevant art(s).

In yet another embodiment, the invention is implemented using a combination of both hardware and software.

Although several variants of the invention have been described, they should not be construed to limit the spirit and scope of the appended claims. Those skilled in the art will understand that various modifications may be made to the described embodiment. Moreover, to those skilled in the various art, the invention itself herein will suggest solutions to other tasks and adaptations for other applications. It is therefore desired that the present embodiments be considered in all respects as illustrative and not restrictive, reference being made to the appended claims rather than the foregoing description to indicate the spirit and scope of the invention. Although such modifications and changes may be suggested by those skilled in the art, it is the intention of the inventors to embody within the patent warranted hereon all changes and modifications as reasonably and properly come within the scope of their contribution to the art. Thus, the present invention should not be limited by any of the above-described exemplary embodiments, but should be defined only in accordance with the following claims and their equivalents.

1. A transmitter unit for transmitting data via a data link, said transmitter unit comprising a header compression unit adapted for converting a primary header of a data packet to be transmitted into a corresponding secondary header, with said primary header being related to said secondary header in one-to-one correspondence; and wherein said transmitter unit is adapted for transmitting a modified data packet via said data link, said modified data packet comprising said corresponding secondary header.

2. The transmitter unit of claim 1, wherein said data packet is an ATM cell, and wherein said primary header is an ATM header.

3. The transmitter unit of claim 1, wherein said data link is part of an access network, in particular of an xDSL network.

4. The transmitter unit of claim 1, wherein said modified data packet is a fixed packet size.

5. The transmitter unit of claim 1, wherein the size of said secondary header is substantially smaller than the size of said primary header.

6. The transmitter unit of claim 1, wherein said header compression unit is adapted for converting said primary header in real-time.

7. The transmitter unit of claim 1, wherein said header compression unit is adapted for removing redundancy check bits that are part of said primary header.

8. The transmitter unit of claim 1, wherein said header compression unit is adapted for copying a predefined part of the bit sequence for said primary headers to said corresponding secondary header without any modification.

9. The transmitter unit of claim 1, wherein said header compression unit is adapted for assigning, whenever a previously unknown primary header is encountered for the first time, a secondary header to said primary header.

10. The transmitter unit of claim 1, wherein said header compression unit comprises at least one lookup table, with said lookup table being accessed for converting said primary header, or a part thereof, into said corresponding secondary header, or a part thereof.

11. The transmitter unit of claim 10, wherein said header compression unit is adapted for creating, whenever said secondary header is assigned to a previously unknown primary header, a corresponding entry in said lookup table.

12. The transmitter unit of claim 10, wherein an entry of said lookup table comprises header information for relating said primary header, or a part thereof, to said corresponding secondary header, or a part thereof.

13. The transmitter unit of claim 10, wherein an entry of said lookup table comprises said primary header, or a part thereof, whereby said corresponding secondary header, or a part thereof, is represented by the respective entry number.

14. The transmitter unit of claim 10, wherein said header compression unit is adapted for searching said lookup table for an entry that matches with said primary header of said data packet to be transmitted, or with a part thereof, and for fetching, in case of a match, said corresponding secondary header, or a part thereof.

15. The transmitter unit of claim 1, wherein said transmitter unit is adapted for transmitting update information packets via said data link, with said update information packets comprising update information for updating at least one lookup table on the part of a receiver unit.

16. The transmitter unit of claim 15, wherein each time a new entry in said at least one lookup table is created, an update information packet comprising header information of said entry is transmitted.

17. The transmitter unit of claim 15, wherein said update information comprises one or more secondary headers, or parts thereof, and for each of said secondary headers, a corresponding primary header said secondary header has been assigned to, or parts thereof.

18. The transmitter unit of claim 1, wherein said secondary header comprises extra bits that are used for transmitting control information.

19. The transmitter unit of claim 1, wherein said secondary header comprises extra bits for accommodating count values required for transmitting said modified data packet in an inverse multiplexing mode.

20. A receiver unit for receiving data transmitted via a data link, said receiver unit comprising a header decompression unit adapted for converting a secondary header of a modified data packet received via said data link into a corresponding primary header, with said secondary header being related to said primary header in one-to-one correspondence.

21. The receiver unit of claim 20, wherein said modified data packet is a fixed packet size.

22. The receiver unit of claim 21, wherein said receiver unit is adapted for performing a cell delineation by counting the bytes received by said receiver unit.

23. The receiver unit of claim 20, wherein said receiver unit is adapted for performing a cell delineation by counting the bytes received by said receiver unit.

24. A method for transmitting data via a data link, said method comprising the steps of:
converting a primary header of a data packet that is to be transmitted via the data link into a corresponding secondary header, with said primary header being related to said secondary header in one-to-one correspondence; and
transmitting a modified data packet via the data link, said modified data packet comprising said corresponding secondary header.

25. The method of claim 24, further comprising the step of removing redundancy check bits that are part of said primary header.

26. The method of claim 24, further comprising the step of copying a predefined part of the bit sequence for said primary header to said corresponding secondary header without any modification.

27. A method for receiving data transmitted via a data link, said method comprising the step of:
converting a secondary header of a modified data packet that has been received via said data link into a corresponding primary header, with said secondary header being related to said primary header in one-to-one correspondence.

28. A method of data transport over an access network, comprising the steps of:
receiving a data packet having a header;
reducing said header in said data packet to create a modified data packet; and
transmitting said modified data packet over the access network.

29. A program stored on a data carrier, capable of executing the method of claim 24.

30. A computer comprising the program of claim 29.
